(19) United States
(12) Patent Application Publication
(10) Pub. No.: US 2012/0229129 A1
(43) Pub. Date: Sep. 13, 2012

(54) PROBE STATION WITH MAGNETIC MEASUREMENT CAPABILITIES

(76) Inventor: Vladimir Kochergin, Christiansburg, VA (US)

(21) Appl. No.: 13/417,240

(22) Filed: Mar. 10, 2012

Related U.S. Application Data
(60) Provisional application No. 61/451,621, filed on Mar. 11, 2011.

(51) Int. Cl. G01R 33/02; G01K 13/00; G01J 4/00; G01R 31/00; G01J 1/00

(52) U.S. Cl. 324/244; 324/750.16; 324/750.03; 356/213; 324/750.01; 356/364; 374/142; 374/E13.001

(57) ABSTRACT

A system for probing with electrical test signals on an integrated circuit specimen in the external multidimensional magnetic field of controlled strength and orientation is provided by utilizing an assembly of cone-shaped electromagnets. In one form the system has an environmental enclosure and environmental control system for testing of an integrated circuit specimen at environmentally controlled conditions. The system of the present invention can be used for probing of electronic and spintronic devices.

### CROSS-REFERENCES TO RELATED APPLICATIONS

Provisional Patent, Probe Station with Magnetic Measurement Capabilities, Application Number 61/451,621.

### STATEMENT REGARDING FEDERALLY SPONSORED RESEARCH OR DEVELOPMENT

None.

### FIELD OF THE INVENTION

The present invention relates to the probe station with external multidimensional magnetic field capabilities, and particularly to the electromagnet design and arrangement that enables multidimensional magnetic field capabilities of the probe station.

### BACKGROUND OF THE INVENTION

Spintronic and magneto-electronic devices (for a nonlimiting example, utilizing giant magnetoresistance effect, GMR) are currently actively used in diverse number of applications. Moreover, with the end of CMOS era approaching, magneto-electronic devices utilizing electron spin as a state variable are considered by many to be a possible replacement for the CMOS technology utilizing electronic charge as the state variable due to significantly smaller power dissipation associated with electronic spin storage and processing. For these reasons testing and characterization of magnetoelectronic devices is important and needed by both industry and academia. Testing of electrical properties of spintronic devices in the presence of external magnetic field is an important type of testing of such device. Depending on particular design of the device such a testing requires external magnetic fields of different strength and different spatial orientation with respect to the spintronic device.

Probe stations with external magnetic field capabilities are usually used for testing and characterization of spintronic devices in external magnetic fields, such as, for a nonlimiting example, a line of magnetic probe stations from Lake Shore Cryotronics Inc. (Westerville, Ohio) or a line of magnetic probe stations from Janis Research Company (Wilmington, Mass.). Such probe stations comprise the pair of magnets positioned either with the axis of said pair of magnet either perpendicular to the plane of the device under test (affixed on the wafer chuck) or in the plane of the device under test. FIG. 1 shows a schematic drawing of the electromagnet assembly, probing assembly and device under test 1.1 on a wafer cuck 1.2 such as used in prior art in-plane magnetic probe stations. The probing assembly comprises micromanipulators 1.3 that provide the lateral movement of the probe arms 1.4 with probe tips 1.5 over the surface of the device under test to permit precise positioning of the probes. Typically electromagnets are used as a source of external magnetic field that consists of the magnetic core 1.6, coils 1.8, magnetic pole 1.7 and magnetic line 1.9 for magnetic flux closure.

The size of the wafer in prior art magnetic probe stations with in-plane external magnetic fields is limited by the spacing between electromagnet poles to typically 1 inch diameter or, in some cases, to 2 inch diameter. At present, 4 inch or 6 inch wafers are typically used in research and development, while 8 inch and 10 inch wafers are typically used in production, with 12 inch diameter wafers expected to be used for production in the future. Limitation on the wafer size by state of the art probe stations with in-plane external magnetic field capabilities means that in most cases testing of the spintronic devices on the wafer cannot be done and specific sample preparation (cleaving or dicing of the wafer) is needed before the testing of spintronic devices on state of the art magnetic probe stations. This is a serious deficiency which leads not only to much longer time needed for the testing of devices, but also, due to destructive nature of the required sample preparation process, prohibiting further processing of the tested wafers.

Moreover, the large size of the electromagnets used in prior art magnetic probe stations is prohibiting utilization of multidimensional external magnetic fields with reasonable strengths (in excess of 100 gauss), leading to the availability of availability of state of the art magnetic probe stations with either in-plane single axis sufficiently strong external magnetic fields or with perpendicular single axis external magnetic fields. This often results in the need for end user to purchase two probe stations and very lengthy characterization process to fully characterize the spintronic device.

Another serious deficiency of prior art magnetic probe stations is stemming from the fact that large size electromagnets used in prior art probe stations require lengthy probe arms, which subject to move during the application of external magnetic fields. While state of the art magnetic probe stations are designed to have this movement to below 0.5 micrometer, this movement is still unacceptable to many state of the art devices which are smaller in sizes.

Thus, there is a clear need for a probe station capable of providing multidimensional external magnetic field capabilities and capable of characterizing spintronic devices on full wafers.

### SUMMARY OF THE INVENTION

It is an object of the present invention to provide a new probe station with multidimensional external magnetic field capability and ability to test devices on the wafer scale. The enabling technology for the magnetic probe station of the present invention is special cone-shaped electromagnet assembly that permit generating strong magnetic fields in the position of the device under test while resolving spatial constrains associated with the electromagnet assembly, wafer chuck and electrical probe positioning with respect to each other.

According to the present invention a probe station for measurements of a device under test in external magnetic field comprises: a wafer chuck assembly for holding a device under test having an upper surface; a holder for holding at least one electrical probe; a positioning mechanism for selectively moving at least one of said chuck assembly and said holder toward or away from the other to enable said probe to contact said device; and an electromagnet assembly for application of magnetic field, said electromagnet assembly having at least two pairs of cone-shaped electromagnets.

According to the first embodiment of the present invention, the probe station's electromagnet assembly comprises two pairs of cone-shaped electromagnets, each pair of electromagnets having a common axis, and said common axes of each pair being in the same plane which is perpendicular to the plane of the wafer. Moreover, said common axes of each pair are having a single point of intersection, with said point of intersection being not more than one centimeter away from the upper surface of wafer chuck assembly. In one of the exemplary arrangements each of said axes is oriented at roughly 45° with respect to the normal direction to the wafer surface and thus roughly perpendicular to each other. With such an arrangement of electromagnets an arbitrary orientation of external magnetic field in the plane containing said axes is obtainable at the location of test device. In one realization the rotational member is provided in a probe station, which enables rotation of the wafer chuck with the device under test with respect to the electromagnet assembly, which permits evaluation of the device under test in arbitrary three-dimensional orientation of external magnetic field.

According to the second embodiment of the present invention the probe station's electromagnet assembly comprises three pairs of cone-shaped electromagnets, each pair of electromagnets having a common axis, and said common axes of each pair having a single point of intersection, with said point of intersection being not more than one centimeter away from the upper surface of a chuck assembly. In one of the exemplary arrangements each of said axes is oriented roughly orthogonally with respect to other axes and at roughly equal angles with respect to the normal direction to the wafer surface. With such an arrangement of electromagnets an arbitrary three-dimensional orientation of external magnetic field is obtainable at the location of test device.

Depending on the required strength of the external magnetic field cone-shaped electromagnets comprising electromagnet assembly can be just a cone-shaped coil winded onto nonmagnetic bobbin (if the fields lower than few hundreds of gauss are needed by application). Alternatively, the cone shaped electromagnets may comprise a cone-shaped coil winded onto the magnetic core, if the magnetic fields in few thousands of gauss are needed. Still, alternatively, the magnetic back plate and/or magnetic cone-shaped cover can be utilized if the fields close to or exceeding 1 T are required.

Associated with the probe station of the present invention instrumentation further includes at least one current source to provide the adjustable current to the electromagnets. To provide accurate setting of the strength and orientation of the external magnetic field in the probe station of the present invention at least one magnetic sensor can be utilized in vicinity of said electromagnets to measure magnetic fields and to provide active feedback to the current source. At least one temperature sensor can be provided to measure the temperature of electromagnets. The cooling means can be further provided to prevent the overheating of electromagnets.

An optical microscope can be further provided with the probe station of the present invention. According to one aspect of the present invention said optical microscope can be a polarizing microscope which can be configured to measure and record spatial distributing of polarization rotation caused by the device under test. With such an arrangement the magnetic domains in the device under test may be imaged during testing.

According to another aspect of the present invention, the probe station further comprises a vacuum housing, such as the device under test is disposed in vacuum conditions during testing operations. According to still another aspect of the present invention the heat shield is provided around the device under test to thermally insulate the device under test from outside heat sources and from the heat generated by electromagnets during testing. According to another aspect of the present invention the environmental control system is provided to control the temperature of the device under test during testing. Further, the probe station of the present invention may contain an electromagnetic shielding for shielding device under test from other sources of electromagnetic field than those provided by cone-shaped electromagnet assembly. Such a shield is especially useful for high accuracy low magnetic field measurements as well as for radio frequency (RF) device testing.

The probe station of the present invention can be used for angular dependent and anisotropic magneto-transport measurements, for testing and characterization of various magnetoelectronic devices (for a nonlimiting illustrative example, GMR-based or spin torque-based, as well as various RF and microwave devices) as well as for testing of magneto-electronic characteristics of various nanoscale devices.

### BRIEF DESCRIPTION OF THE DRAWINGS

These and other features and advantages of presently preferred non-limiting illustrative exemplary embodiments will be better and more completely understood by referring to the following detailed description in connection with the drawings, of which:

FIG. 1 is a schematic illustrative drawings of the electromagnet assembly, probing assembly and device under test on a wafer cuck of the prior art probe station with external in-plane magnetic field capability with left figure illustrating the top view of the prior art probe station components while right figure illustrating the side view of the prior art probe station components;

FIG. 2a is a perspective view of the probe station of the present invention with three-dimensionally controlled external magnetic field capabilities.

FIG. 2b is a front view of a probe station of the present invention with three-dimensionally controlled external magnetic field capabilities.

FIG. 3a is a schematic exemplary drawing illustrating a cone-shaped electromagnet assembly such as required for the probe station of the present invention with two-dimensionally controlled external magnetic field capabilities.

FIG. 3b is a schematic exemplary drawing illustrating a cone-shaped electromagnet assembly such as required for the probe station of the present invention with three-dimensionally controlled external magnetic field capabilities.

FIG. 4 is a schematic exemplary drawing illustrating geometrical limitations of the cone-shaped electromagnet such as can be used in the probe station of the present invention with multidimensionally controlled external magnetic field capabilities.

FIG. 5 is a schematic exemplary drawing illustrating one possible realization of a single pair of electromagnets such as used in the probe station of the present invention.

FIG. 6 is a plot of the magnetic field in the gap between cone-shaped electromagnet versus electrical current with and without the ferromagnetic back-plate.

FIG. 7 is an exemplary drawing illustrating different geometries of individual electromagnets and their respective positioning with respect to the device under test as can be used in a the probe station of the present invention.

FIG. 8 is a schematic exemplary drawing illustrating a cone-shaped electromagnet with two different wire coils that can be used in a probe station of the present invention to increase the dynamic range of external magnetic field.

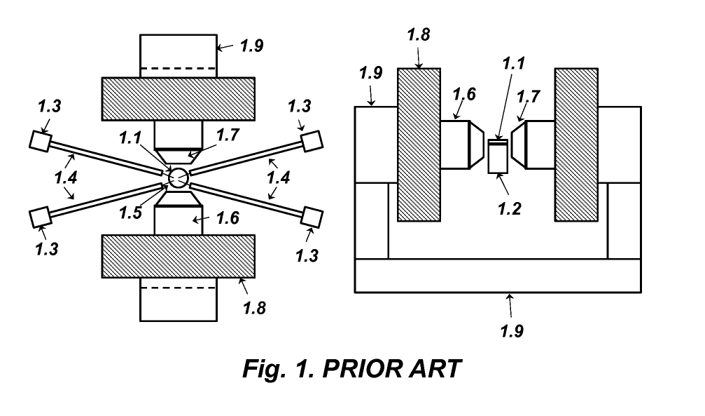

### DESCRIPTION OF THE INVENTION

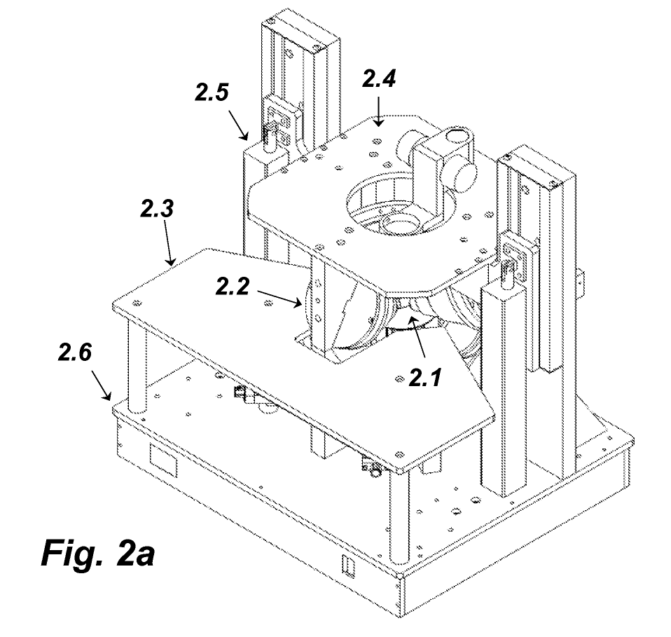

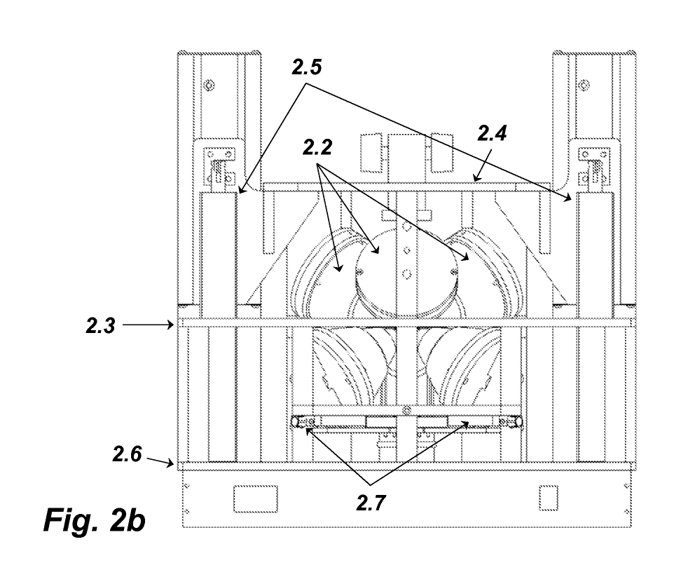

According to the drawings and especially to FIGS. 2a and 2b, the probe station of the present invention for measurements of a device under test in external magnetic field comprises: a wafer chuck assembly 2.1 for holding a semiconductor wafer or its portion containing one or more device under test; a holder 2.3 for holding at least one electrical probe; a positioning mechanism 2.7 for selectively moving at least one of said chuck assembly and said holder toward or away from the other to enable said probe to contact said device; and an electromagnet assembly 2.2 for application of magnetic field, said electromagnet assembly having at least two pairs of cone-shaped electromagnets. According to one illustrative example, half of cone-shaped electromagnets can be affixed to the base plate 2.6 of the probe station, while another half of cone-shaped electromagnets can be affixed to the upper plate 2.4 that also serves as a holder to the microscope. According to another illustrative example, the top plate 2.4 can be raised and lowered mechanically either manually or with the help of actuators 2.5 to simplify loading and unloading of the device under test into the probe station of the present invention.

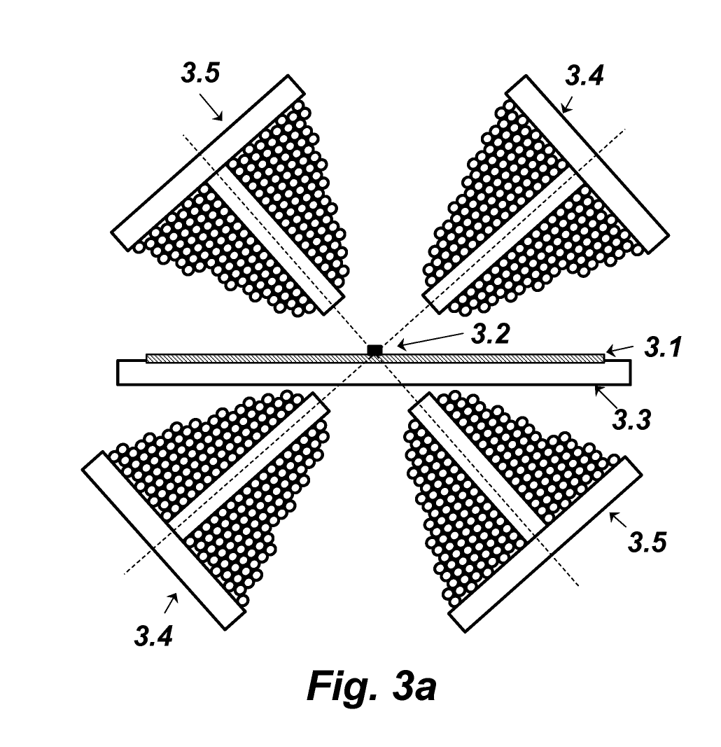

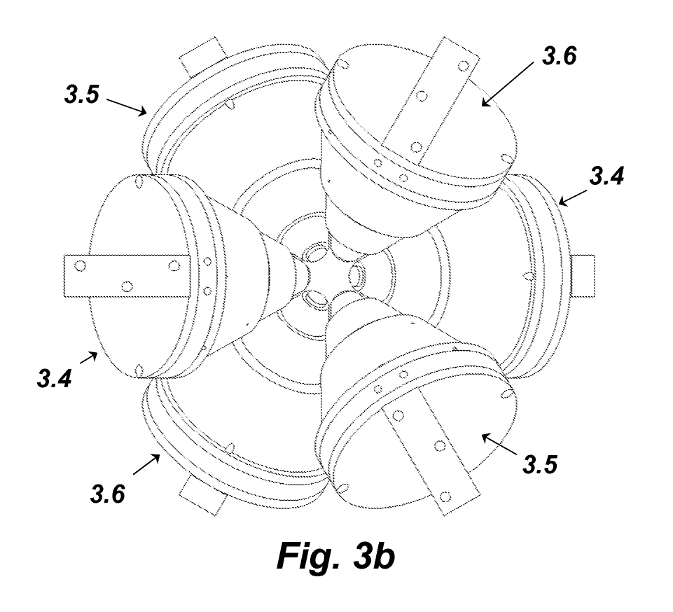

According to the first embodiment of the present invention illustrated schematically in FIG. 3a, the probe station's electromagnet assembly comprises two pairs of cone-shaped electromagnets (3.4 and 3.5 respectively), each pair of electromagnets having a common axis, and said common axes of each pair being in the same plane which is perpendicular to the plane of the wafer 3.1 containing at least one device under test 3.2. Moreover, said common axes of each pair are having a single point of intersection, with said point of intersection being not more than one centimeter away from the upper surface of wafer chuck assembly and preferably within one millimeter of the upper surface of the wafer chuck unless thicker wafers and devices are to be tested. In one of the exemplary arrangements each of said axes is oriented at roughly 45° with respect to the normal direction to the wafer surface and thus roughly perpendicular to each other. With such an arrangement of electromagnets an arbitrary orientation of external magnetic field in the plane containing said axes is obtainable at the location of test device. In one realization the rotational member is provided in a probe station, which enables rotation of the wafer chuck with the device under test with respect to the electromagnet assembly, which permits evaluation of the device under test in arbitrary three-dimensional orientation of external magnetic field.

According to the second embodiment of the present invention illustrated in FIG. 3b, the probe station's electromagnet assembly comprises three pairs of cone-shaped electromagnets (3.4, 3.5 and 3.6 respectively), each pair of electromagnets having a common axis, and said common axes of each pair having a single point of intersection, with said point of intersection being not more than one centimeter away from the upper surface of a chuck assembly and preferably within 1 millimeter of the upper surface of the wafer chuck unless thicker wafers and devices are to be tested. In one of the exemplary arrangements each of said axes is oriented roughly orthogonally with respect to other axes and at roughly equal angles with respect to the normal direction to the wafer surface. In such a nonlimiting example, if the axes of cone-shaped electromagnets are oriented along (100), (010) and (001) directions the normal direction to the wafer chuck will be (111) direction in such a Cartesian coordinate system. Alternatively, the coil pairs may not be orthogonal to each other, if the maximum achievable magnetic fields in in-plane and perpendicular directions are desired to be substantially different. With such an arrangement of electromagnets an arbitrary three-dimensional orientation of external magnetic field is obtainable at the location of the device under test.

Utilization of such probe station designs will allow end user to test magnetoelectronic and spintronic devices and materials in in-plane and perpendicular external magnetic fields in a single system, eliminating the expensive and lengthy characterization process required when using prior art probe stations. Moreover, by moving the wafer chuck assembly with the wafer laterally with respect to the electromagnet arrangement, the testing and characterization over full surface of 4 inch, 6 inch, 8 inch or 10 inch diameter wafer can be performed, removing the need for lengthy sample preparation required when using prior art probe stations.

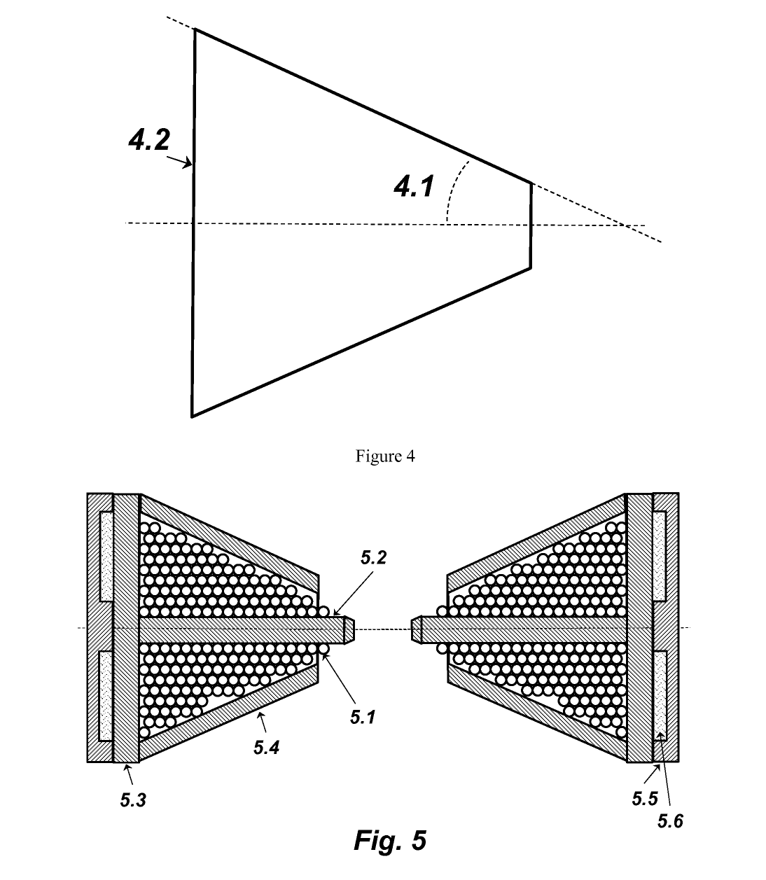

The enabling element of the probe station of the present invention is the cone-shaped electromagnet that permits achieving high levels of magnetic field around device under test while permitting to use device under test on a full wafer. Various arrangements of electromagnets permitting two or three-dimensionally controlled strength and orientation of magnetic field are known to those skilled in the art. The most common type of such electromagnets is the arrangement of three mutually perpendicular pairs of Helmholtz coils. However, such electromagnet arrangement is capable of generating only weak magnetic fields (with 10 s of gauss level being the typical limit), insufficient for the vast majority of magneto-electronic or magneto-transport applications. Similar to three pairs of Helmhotz coil, arrangement of prior art superconducting magnets or C-shaped magnets with magnetic core is incompatible with the probe stations capable of handling devices on semiconductor wafer. The geometrical limitations for the electromagnet shape are illustrated in FIG. 4 showing the limiting angle 4.1 and possible shape of electromagnet 4.2. Each electromagnet should fit into the cone (with angle 4.1 being not more than 45 degrees angle for the probe station with two pairs of electromagnets and with not more than 35.3 degrees for the probe station with the three pairs of electromagnets). Moreover, there are limit associated with the distance between the tip of the cone and the surface of electromagnet (in the nonlimiting illustrative example in can be in 5 mm to 30 mm range), as well as practical limitations on the electromagnet size and weight. Thus, utilization of cone-shaped electromagnets as provided in nonlimiting illustrative schematic drawing in FIG. 5, will enable the probe station of the present invention.

Depending on the required strength of the external magnetic field cone-shaped electromagnets comprising electromagnet assembly (such as shown for a single pair of electromagnets in FIG. 5) can be just a cone-shaped coil 5.1 winded onto nonmagnetic bobbin 5.2 (if the fields lower than few hundreds of gauss are needed by application). The wire gage, the number of turns, the angle of the cone and the size of the cone are to be defined by a particular application requirement, particularly, by the interplay between the desired field uniformity and field strength.

The cone shaped electromagnets may comprise a cone-shaped coil 5.1 winded onto the ferromagnetic core 5.2, if the magnetic fields in few thousands of gauss are needed in the location of device under test. The ferromagnetic core 5.2 can be made of soft, high permeability magnetic materials if maximum magnetic fields in the 3,000 gauss range are needed, such as for a nonlimiting example, Moly-Permalloy, EFI alloy 79 HyMu 80, Hyperco 50, Fe₄₉Ni₄₈Si_{0.35}Mn_{0.5} or any other high permeability soft magnetic material known to those skilled in the art. The choice of particular material is defined by the interplay between the saturation induction, maximum permeability, coercive force and cost/processing requirements. If higher maximum magnetic fields in excess of 3000 gauss are needed in the location of device under test, hard magnetic materials are needed, such as for a nonlimiting example, AlNiCo, rear earth magnets or any other hard magnetic materials known to those skilled in the art. The choice of particular magnetic material in such a case is defined by the interplay between the saturation induction, maximum permeability, coercive force and cost/processing requirements.

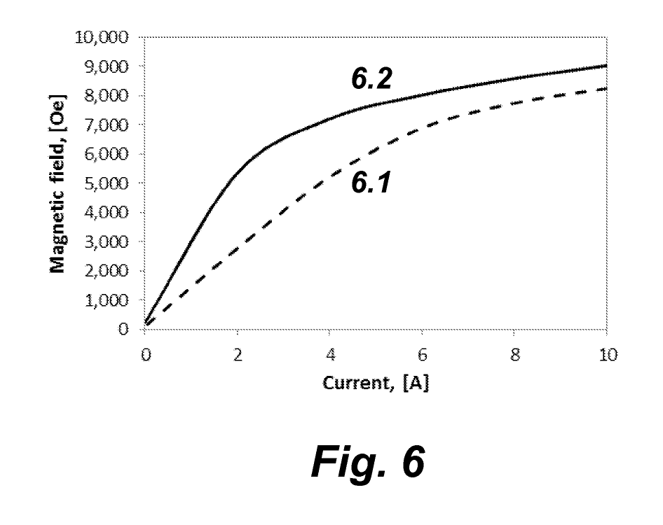

Still, alternatively, the cone shaped electromagnets may comprise a cone-shaped coil 5.1 winded onto the ferromagnetic core 5.2 with the magnetic back plate 5.3 and/or magnetic cone-shaped cover 5.4 can be utilized if the fields close to or exceeding 1 T are required. Similarly to magnetic core materials discussed above, the magnetic parts 5.2, 5.3, and 5.3 can be made of magnetically soft or hard materials known to those skilled in the art. Moreover, different materials can be utilized in these parts. Utilization of magnetic back-plate and magnetic con-shaped cover permits suppressing magnetic flux leakage at the vicinity of the cone tip and provides thus higher values of magnetic fields between the cone-shaped electromagnet pair. As a nonlimiting example, FIG. 6 shows plots of magnetic field between the pair of cone-shaped electromagnets without magnetic back plate (curve 6.1) and with the back plate made of Carpenter's Stainless type 430FR solenoid quality steel (curve 6.2). Carpenter's Hyperco 50 core was used in such a demonstration. The significantly enhanced at low currents generated magnetic field is shown.

Depending on the driving current required and the heat dissipation, the cone-shaped electromagnets may also comprise a liquid cooling channels 5.6 provided in a cooling plate 5.6.

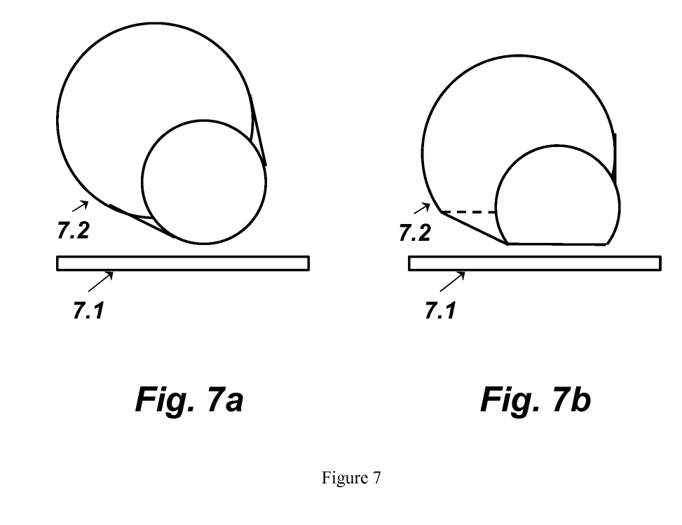

FIG. 7 illustrates that besides axially symmetrical conical shape electromagnets (7.2) as in FIG. 7a, non-axially symmetric electromagnets as in FIG. 7b can be used in the probe station of the present invention to bring the electromagnet closer to the wafer and wafer chuck 7.1 and thus to achieve higher magnetic fields at the position of device under test.

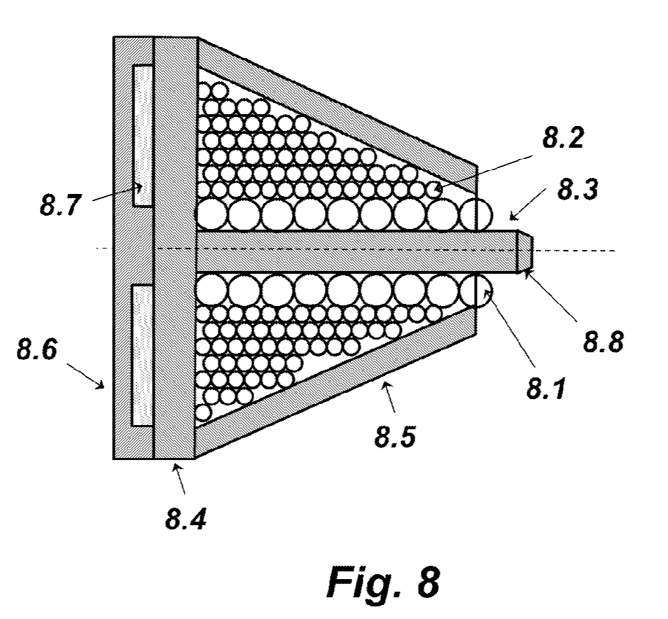

FIG. 8 illustrates that the electrical coil of cone-shaped electromagnet can comprised two or more electrically insulated between each other coils (8.1 and 8.2) driven by different current sources, with said coils winded around magnetic or nonmagnetic core 8.3. With such a realization of cone-shaped electromagnet the magnetic back plate 8.4, magnetic cone-shaped cover 8.5, cooling channels 8.7 confined by the cooling plate 8.7 can be used, so as the tapered end of the core 8.8. Use of two or more electrical coils driven by two or more current sources are desirable when the dynamic range of the probe station of the present invention in excess of the dynamic range of practical current source is required.

Associated with the probe station of the present invention instrumentation further includes at least one current source to provide the adjustable current to the electromagnets. Preferably, the individual, current sources for each pair of electromagnets are needed. To provide accurate setting of the strength and orientation of the external magnetic field in the probe station of the present invention at least one magnetic field sensor can be utilized in vicinity of said electromagnets to measure magnetic fields and to provide active feedback to the current source. Preferably, at least one magnetic field sensor (such as Hall probe-type sensor) is required to be used for each electromagnet pair to improve the accuracy of the magnetic field generated at the position of device under test. At least one temperature sensor can be provided to measure the temperature of electromagnets. The cooling means can be further provided to prevent the overheating of electromagnets.

An optical microscope can be further provided with the probe station of the present invention. According to one aspect of the present invention said optical microscope can be a polarizing microscope which can be configured to measure and record spatial distributing of polarization rotation caused by the device under test. With such an arrangement the magnetic domains in the device under test may be imaged during testing.

According to another aspect of the present invention, the probe station further comprises a vacuum housing, such as the device under test is disposed in vacuum conditions during testing operations. According to still another aspect of the present invention the heat shield is provided around the device under test to thermally insulate the device under test from outside heat sources and from the heat generated by electromagnets during testing. According to another aspect of the present invention the environmental control system is provided to control the temperature of the device under test during testing. Further, the probe station of the present invention may contain an electromagnetic shielding for shielding device under test from other sources of electromagnetic field than those provided by cone-shaped electromagnet assembly. Such a shield is especially useful for high accuracy low magnetic field measurements as well as for radio frequency (RF) device testing.

The probe station of the present invention can be used for angular dependent and anisotropic magneto-transport measurements, for testing and characterization of various magnetoelectronic devices (for a nonlimiting illustrative example, GMR-based or spin torque-based, as well as various RF and microwave devices) as well as for testing of magneto-electronic characteristics of various nanoscale devices.

What is claimed is:

1. A probe station for measurements of a device under test in external magnetic field comprising:
A chuck assembly for holding a test device having an upper surface;
A holder for holding at least one electrical probe;
A positioning mechanism for selectively moving at least one of said chuck assembly and said holder toward or away from the other to enable said probe to contact said device; and
An electromagnet assembly for application of magnetic field, said electromagnet assembly having at least two pairs of cone-shaped electromagnets.

2. The probe station of claim 1, wherein the electromagnet assembly comprises:
Two pairs of cone-shaped electromagnets;
Each pair of cone-shaped electromagnets having a common axis;
Said common axes of each pair of cone-shaped electromagnets being in the same plane which is essentially perpendicular to the plane of the chuck assembly upper surface; and
Said common axes of each pair of cone-shaped electromagnets being oriented at predetermined angle with respect to each other, with said angle being in the 45 degrees to 135 degrees range.

3. The probe station of claim 1, wherein the electromagnet assembly comprises:
Three pairs of cone-shaped electromagnets;
Each pair of cone-shaped electromagnets having a common axis;
Said common axes of each pair of cone-shaped electromagnets having a single point of intersection; and
Said point of intersection being not more than 1 cm from upper surface of chuck assembly.

4. The probe station of claim 3, wherein the common axes of each pair of cone-shaped electromagnets are essentially perpendicular to each other.

5. The probe station of claim 1, wherein the cone-shaped electromagnet comprises a cone-shaped conductive coil.

6. The probe station of claim 1, wherein the cone-shaped electromagnet comprises a cone-shaped conductive coil winded around the ferromagnetic core.

7. The probe station of claim 1, wherein the cone-shaped electromagnet comprises a cone-shaped conductive coil winded around the ferromagnetic core, and a ferromagnetic back-plate.

8. The probe station of claim 1, wherein the cone-shaped electromagnet comprises: a cone-shaped conductive coil winded around the ferromagnetic core; a ferromagnetic back-plate; and a ferromagnetic cone-shaped cover.

9. The probe station of claim 1, wherein the cone-shaped conductive coil is composed of two or more coils made of conductive wires of different diameter.

10. The probe station of claim 1 further comprising at least one magnetic field sensor around electromagnet assembly to provide magnetic field measurements.

11. The probe station of claim 1 further comprising at least one temperature sensor in thermal contact with at least one cone-shaped electromagnet to provide temperature measurements of said electromagnet.

12. The probe station of claim 1 further comprising a microscope for acquiring images of the device under test.

13. The probe station of claim 12 wherein the microscope is a polarizing microscope.

14. The probe station of claim 1 further comprising a vacuum housing having an interior space in which a device under test is disposed with the interior space under vacuum conditions during testing operations.

15. The probe station of claim 14 further comprising a heat shield for improved thermal insulation of the device under test during testing operations.

16. The probe station of claim 14 further comprising an environmental control system for setting and maintaining the temperature of the device under test during testing operations.

17. The probe station of claim 1 further comprising an electromagnetic shielding having an interior space in which a device under test is disposed.
